(19) United States
(12) Patent Application Publication
(10) Pub. No.: US 2008/0030283 A1
(43) Pub. Date: Feb. 7, 2008

(54) Circuit, Manufacturing Method And Inverter circuit For Discharge Tube

(75) Inventor: Masakazu Ushijima, Tokyo (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Greatchip Technology Co., Ltd., Taichung (TW)

(21) Appl. No.: 11/830,302

(22) Filed: Jul. 30, 2007

(30) Foreign Application Priority Data
Aug. 1, 2006 (JP) 2006-210369

(51) Int. Cl. H03H 2/00; H01F 5/00; H01F 7/06; H02M 7/537

(52) U.S. Cl. 333/24 R; 29/602.1; 336/200; 363/131

(57) ABSTRACT

A circuit includes a first circuit including therein a first coil connected to a power source and a first capacitance component, and a second circuit including therein a second coil connected to the power source and a second capacitance component, wherein the second coil is avenged so as to generate a magnetic field in such a direction as to offset a magnetic field generated by a current flowing through the first coil. Here, a self inductance of the first coil is substantially the same as a self inductance of the second coil, currents flowing through the first and second coils are made substantially the same by a mutual inductance between the first and second coils, a leakage inductance component of the first coil and the first capacitance component form a resonance circuit, and a leakage inductance component of the second coil and the second capacitance component form a resonance circuit.

### CROSS REFERENCE TO RELATED APPLICATION

The present application claims priority from a Japanese Patent Application No. 2006-210369 filed on Aug. 1, 2006, the contents of which are incorporated herein by reference.

### BACKGROUND

1. Technical Field

The present invention relates to a circuit, a manufacturing method, and an inverter circuit for a discharge tube. More particularly, the present invention relates to a circuit and an inverter circuit for a discharge tube which has a plurality of coils provided therein, and a manufacturing method for the circuit.

2. Related Art

Area light sources which are recently used as backlights in liquid crystal televisions and the like are formed by using a large number of discharge tubes and light-enitting diodes. Such discharge tubes include, for example, cold cathode fluorescent lamps and external electrode cold cathode fluorescent lamps. For example, area light sources that are used as backlights in liquid crystal televisions are strongly required to be uniform in terms of luminance, for example. To satisfy this request, the inventor of the present invention has already disclosed multiple methods (for example, see Patent Documents 1 to 8)

[Patent Document 1] Unexamined Japanese Patent Application Publication No-2004-335443

[Patent Document 2] Unexamined Japanese Patent Application Publication No. 2005-203347

[Patent Document 3] Unexamined Japanese Patent Application Publication No. 2006-12781

[Patent Document 4] Unexamined Japanese Patent Application Publication No. 2006-108667

[Patent Document 5] U.S. Patent Application Publication No. 2004-0155596

[Patent Document 6] U.S. Patent Application Publication No. 2005-0218827

[Patent Document 7] U.S. Patent Application Publication No. 2006-055338

[Patent Document 8] U.S. Patent Application Publication No. 2006-0066246

It is desired to enhance the efficiency of and lower the cost of inverter circuits which are used to drive backlight area light sources. Here, according to the conventional art, the light-up apparatus for the discharge tubes requires one voltage step-up transformer of the leakage flux type for each cold cathode fluorescent lamp. Therefore, the inverter circuit for use with the backlight area light source uses a large number of voltage step-up transformers of the leakage flux type. One of the methods to drive such an inverter circuit for use with the backlight area light source is to cause a large number of cold cathode fluorescent lamps to light up in parallel. According to an exemplary driving method, one voltage step-up transformer is provided for each cold cathode fluorescent lamp and the primary windings of the voltage step-up transformers are connected to the power source in parallel, as shown in FIG. 16. This method is generally referred to as a “one by one” method. This technique is often employed in low-cost inverter circuits for use with backlight area light sources. This method, however, has drawbacks of variances in terms of various characteristics, such as a variance in impedance among the cold cathode fluorescent lamps and a variance in parasitic capacitance formed between the cold cathode fluorescent lamps and adjacent conductors which are used as the reflective boards for the cold cathode fluorescent lamps. Therefore, this technique does not assure that each cold cathode fluorescent lamp always has au equal tube current. Consequently, the backlight area light source has a problem of unevenness in luminance.

According to the conventional technique, the number of stages of power conversion is large. For example, power is supplied from a commercial power source, sent via a PFC circuit, and converted into DC power by a DC/DC converter. The generated DC power is further converted into a high-frequency high voltage by means of the inverter circuit for use with the discharge tubes. The high-frequency high voltage is thus used to drive the discharge tubes. This method requires three stages of power conversion. Here, each stage of power conversion degrades the efficiency. Therefore, it is highly desirable to reduce the number of stages of power conversion to improve the overall efficiency. Here, a fairly large part of the efficiency degradation is attributed to the voltage step-up transformers. This indicates that the efficiency can be significantly improved by removing the voltage step-up transformers. In light of this idea, a method has been proposed which produces DC high voltage (generally in are from approximately 360 VDC to approximately 400 VDC) by means of a PFC power source, generates AC voltage by directly switching on/off the DC high voltage, and steps up the AC voltage by means of a serial resonance circuit (see FIG. 17).

The reference signs Q1 and Q2 indicate switching circuits which switch on/off the DC high voltage supplied from the PFC circuit, L1 to L4 indicate choke coils, Ca indicates resonance capacitors, and DT indicates discharge tubes. Each discharge tube has a parasitic capacitance Cs. This circuit steps up the voltage based on the resonance between the choke coils and the resonance capacitors, and can produce a high voltage (approximately several hundred voltage to 2000 V) necessary for the discharge tubes when driven at a frequency in the vicinity of the LC resonance frequency.

Nevertheless, this circuit is subject to the variance in resonance frequency and load among the resonance circuits which is attributed to the variance in parameters such as the inductances of the choke coils and the parasitic capacitances of the discharge tubes. With different load and parasitic capacitance values) each resonance circuit has a different voltage stepping-up ratio as shown in FIG. 18, for example. Such a difference in voltage stepping-up ratio causes a variance in brightness among the discharge tubes, resulting in uneven luminance for the area light source. Here, as the Q values of the resonance circuits are increased, the range for the optimal driving frequency is narrowed. Therefore, driving means of the separately excited resonance type having a fixed frequency does not accomplish a sufficient voltage stepping-up ratio in many cases.

A circuit of the both-side high-voltage driving type shown in FIG. 19 often suffers from a so-called bias phenomenon. This phenomenon is explained in detail in Unexamined Japanese Patent Application Publication No. 2005-203347 and U.S. Patent Application Publication No. 2005-02188271. This problem is also caused by the fact that each resonance circuit has a different resonance frequency.

Therefore, it is an object of an aspect of the present invention to provide a circuit, a manufacturing method and an inverter circuit for a discharge tube, which are capable of overcoming the above drawbacks accompanying the related art. The above and other objects can be achieved by combinations described in the independent claims. The dependent claims define ether advantageous and exemplary combinations of the present invention.

According to a first aspect related to the innovations herein, one exemplary circuit may include a circuit including a first circuit that includes therein a first coil connected to a power source and a first capacitance component, and a second circuit that includes therein a second coil connected to the power source and a second capacitance component, wherein the second coil is arranged so as to generate a magnetic field in such a direction as to offset a magnetic field generated by a current flowing through the first coil. Here, a self inductance of the first coil is substantially the same as a self inductance of the second coil, currents flowing through the first and second coils are made substantially the same by a mutual inductance between the first and second coils, a leakage inductance component of the first coil and the first capacitance component form a resonance circuit, and a leakage inductance component of the second coil and the second capacitance component form a resonance circuit.

The circuit may further include a third circuit that includes therein a third coil connected to the power source and a third capacitance component, wherein the third coil is arranged so as to generate a magnetic field in such a direction as to offset the magnetic field generated by the current flowing through the first coil and the magnetic field generated by the current flowing through the second coil. Here, a coupling coefficient between the third and first coils and a coupling coefficient between the third and second coils may be substantially the same as a coupling coefficient between the first and second coils, and the currents flowing through the first, second and third coils may be adjusted so as to be substantially the same, a leakage inductance component of the first coil and the first capacitance component may form a resonance circuit, a leakage inductance component of the second coil and the second capacitance component may form a resonance circuit, and a leakage inductance component of the third coil and the third capacitance component may form a resonance circuit.

The circuit may further include a first closed circuit that includes herein a first winding portion magnetically coupled to the first coil and a second winding portion magnetically coupled to the second coil, wherein the second winding portion and the second coil have a coupling coefficient therebetween which is substantially the same as a coupling coefficient between the first coil and the first winding portion. Here, the first closed circuit may be formed by connecting the first and second winding portions to each other so that the magnetic field generated in the first coil by the current flowing through the first coil generates an induced current in the first closed circuit which flows in such a direction that a magnetic field is generated in the second winding portion in such a direction as to offset the magnetic field generated in the second coil by the current flowing through the second coil.

The circuit may include a first structure that includes therein the first and second circuits and the first closed circuit, a second structure that includes therein a fourth circuit that includes therein a fourth coil connected to the power source and a fourth capacitance component, a fifth circuit that includes therein a fifth coil connected to the power source and a fifth capacitance component, wherein the fifth coil is arranged so as to generate a magnetic field in such a direction as to offset a magnet field generated by a current flowing through the fourth coil, and a second closed circuit that includes therein a fourth winding portion magnetically coupled to the fourth coil and a fifth winding portion magnetically coupled to the fifth coil, wherein the fifth winding portion and the fifth coil have a coupling coefficient therebetween which is substantially the same as a coupling coefficient between the fourth coil and the fourth winding portion, wherein a self inductance of the fourth coil may be substantially the same as a self inductance of the fifth coil, currents flowing through the fourth and fifth coils may be made substantially the same, a leakage inductance component of the fourth coil and the fourth capacitance component may form a resonance circuit, a leakage inductance component of the fifth coil and the fifth capacitance component may form a resonance circuit, and the second closed circuit may be formed by connecting the fourth and fifth winding portions to each other so that the magnetic field generated in the fourth coil by the current flowing through the fourth coil generates an induced current in the second closed circuit which flows in such a direction that a magnetic field is generated in the fifth winding portion in such a direction as to offset the magnetic field generated in the fifth coil by the current flowing through the fifth coil, and a current transformer that has the first closed circuit on a primary side thereof and the second closed circuit on a secondary side thereof.

The circuit may further include a magnetic member that is provided in a vicinity of the first and second coils so as to oppose the magnetic fields generated by the first and second coils. Here, the magnetic member may guide the magnetic field generated by the first coil to the second coil and guide the magnetic field generated by the second coil to the first coil.

The first and second coils may generate the magnetic fields in substantially the same direction, and the magnetic member may include an auxiliary winding that is wound around the magnetic member in a direction substantially parallel to a direction in which a winding of the first coil and a winding of the second coil are wound.

The circuit may include a first structure that includes therein the first and second coils, the magnetic member and the auxiliary winding, and a second structure that includes therein a fourth circuit that includes therein a fourth coil connected to the power source and a fourth capacitance component, a fifth circuit that includes therein a fifth coil connected to the power source and a fifth capacitance component, wherein the fifth coil is arranged so as to generate a magnetic field in such a direction as to offset a magnetic field generated by a current flowing through the fourth coil, a magnetic member that is provided in a vicinity of the fourth and fifth coils so as to oppose the magnetic fields generated by the fourth and fifth coils, wherein the magnetic member guides the magnetic field generated by the fourth coil to the fifth coil and guides the magnetic field generated by the fifth coil to the fourth coil, and an auxiliary winding that is wound around the magnetic member in a direction substantially parallel to a direction in which a winding of the fourth coil and a winding of the fifth coil are wound. Here, a self inductance of the fourth coil may be substantially the same as a self inductance of the fifth coil, currents flowing through the first and second coils may be made substantially the same, a leakage inductance component of the fourth coil and the fourth capacitance component may form a resonance circuit, and a leakage inductance component of the fifth coil and the fifth capacitance component may form a resonance circuit. Here, the auxiliary winding of the first shuck and the auxiliary winding of the second structure may form a closed circuit.

The circuit may further include a third circuit that includes therein a third coil connected to the power source and a third capacitance component, wherein the third coil generates a magnetic field in substantially the same direction as the magnetic fields generated by the first and second coils. Here, the magnetic member (i) may be provided in a vicinity of the first, second, and third coils so as to oppose the magnetic fields generated by the first, second and third coils, (ii) may guide the magnetic field generated by the first coil to the second and third coils, (iii) may guide the magnetic field generated by the second coil to the first and third coils, (iv) may guide the magnetic field generated by the third coil to the first and second coils, and (v) a flux path between the first and second coils, a flux path between the second and third coils, and a flux path between the third and first coils may have substantially the same length, a leakage inductance component of the first coil and the first capacitance component may form a resonance circuit, a leakage inductance component of the second coil and the second capacitance component may form a resonance circuit, and a leakage inductance component of the third coil and the third capacitance component may form a resonance circuit.

According to a second aspect related to the innovations herein, one exemplary manufacturing method may include a manufacturing method for manufacturing a circuit. The manufacturing method includes forming a first circuit that includes therein a first coil connected to the power source and a first capacitance component, forming a second circuit that includes therein a second coil connected to the power source and a second capacitance component, wherein the second coil is arranged so as to generate a magnetic field in such a direction as to offset a magnetic field generated by a current flowing through the first coil, and the second coil has substantially the same self inductance as the first coil, and arranging the first and second coils in such a manner that (i) a leakage inductance component of the first coil and the first capacitance component form a resonance circuit, (ii) a leakage inductance component of the second coil and the second capacitance component form a resonance circuit, and (iii) a coupling coefficient between the first and second coils falls within a predetermined range in order that currents flowing through the first and second coils become substantially the same.

The arranging may include providing a magnetic member in a vicinity of the first and second coils so as to oppose the magnetic fields generated by the first and second coils, wherein the magnetic member guides the magnetic field generated by the first coil to the second coil and guides the magnetic field generated by the second coil to the first coil, and adjusting a distance between the magnetic member and the first and second coils in order that the coupling coefficient between the first and second coils falls within the predetermined range.

The manufacturing method may further include forming a third circuit that includes therein a third coil connected to the power source and a third capacitance component, wherein the third coil generates a magnetic field in substantially the same direction as the magnetic fields generated by the first and second coils, and the third coil has substantially the same self inductance as the first and second coils. Here, in the arranging, the first, second and third coils may be arranged in such a manner that (i) a leakage inductance component of the first coil and the first capacitance component form a resonance circuit, (ii) a leakage inductance component of the second coil and the second capacitance component form a resonance circuit, (iii) a leakage inductance component of the third coil and the third capacitance component form a resonance circuit, and (iv) a coupling coefficient between the first and second coils, a coupling coefficient between the second and third coils, and a coupling coefficient between the third and first coils fall within a predetermined range in order that the currents flowing through the first, second and third coils become substantially the same, in the magnetic member providing, a magnetic member may be provided in a vicinity of the first and second coils so as to oppose the magnetic fields generated by the first, second and third coils, and the magnetic member (I) may guide the magnetic field generated by the first coil to the second and third coils, (II) may guide the magnetic field generated by the second coil to the first and third coils, and (III) may guide the magnetic field generated by the third coil to the first and second coils, and (IV) may adjust a flux path between the first and second coils, a flux path between the second and third coils, and a flux path between the third and first coils so as to have substantially the same length, and in the distance adjusting, a distance between the magnetic member and the first, second and third coils may be adjusted so that the coupling coefficient between the first and second coils, the coupling coefficient between the second and third coils, and the coupling coefficient between the third and first coils fall within the predetermined range.

According to a third aspect related to the innovations herein, one exemplary inverter circuit for use with discharge tubes may include an inverter circuit for use with discharge tubes. The inverter circuit includes a power source, a first coil connected to a first discharge tube and the power source, and a second coil connected to a second discharge tube and the power source, wherein the second coil is a arranged so as to generate a magnetic field in such a direction as to offset a magnetic field generated by a current flowing through the first coil. Here, a self inductance of the first coil is substantially the same as a self inductance of the second coil, currents flowing through the first and second coils are made substantially the same, a leakage inductance component of the first coil forms a first resonance circuit together with a first capacitance component that at least includes a capacitance component of the first discharge tube, and a leakage inductance component of the second coil forms a second resonance circuit together with a second capacitance component that at least includes a capacitance component of the second discharge tube.

The power source may be a current-resonance-type power source. The inverter circuit may further include a voltage step-up transformer that steps up the voltage supplied by the power source, and supplies the stepped-up voltage to the first and second resonance circuits. Here, the power source may operate at a frequency within such a range that a difference between a voltage phase and a current phase with respect to a primary winding of the voltage step-up transformer is smaller than a predetermined value.

According to a fourth aspect related to the innovations herein, one exemplary circuit may include a circuit including a first circuit that includes therein a first coil connected to a power source, a second circuit that includes therein a second coil connected to the power source, and a third circuit that includes therein a third coil connected to the power source. Here, self inductances of the first, second and third coils axe substantially the same, the first, second and third coils are provided on substantially the same plane and generate agnetic fields in a direction substantially perpendicular to the plane, the first, second and third coils are positioned away from each other at substantially the same distance, and coupling coefficients between the first, second and third coils are substantially the same and fall within a predetermined range.

According to a fifth aspect related to the innovations herein, one exemplary circuit may include a circuit including a first circuit that includes therein a first coil connected to a power source, a second circuit that includes therein a second coil connected to the power source, and a third circuit that includes therein a third coil connected to the power source. Here, self inductances of the first, second and third coils are substantially the same, magnetic fields generated by the first, second and third coils have magnetic axes extending toward substantially the same point, the first, second and third coils are positioned away form the point at substantially the same distance, the first, second and third coils are connected to the power source so as to generate magnetic fields in such directions that the generated magnetic fields offset each other, an angle formed between the magnetic axes of the first and second coils, an angle formed between the magnetic axes of the second and third coils, and an angle formed between the magnetic axes of the third and first coils are substantially the same, and coupling coefficients between the first, second and third coils are substantially the same and fall within a predetermined range.

Here, all the necessary features of the present invention are not listed in the summary. The sub-combinations of the features may become the invention.

### BRIEF DESCRIPTION OF THE DRAWINGS

FIG. 1 illustrates an exemplary configuration of a circuit 100 relating to an embodiment.

FIG. 2 illustrates an exemplary a arrangement of coils 110.

FIG. 3 illustrates a different exemplary arrangement of the coils 110.

FIG. 4 is used to explain current equalization.

FIG. 5 illustrates the relation between the parameters Le, Ls and k.

FIG. 6 illustrates a further different exemplary arrangement of the coils 110.

FIG. 7 illustrates a flirter different exemplary arrangement of the coils 110.

FIG. 8 illustrates a further different exemplary arrangement of the coils 110.

FIG. 9 illustrates a further different exemplary arrangement of the coils 110.

FIG. 10 illustrates a further different exemplary arrangement of the coils 110.

FIG. 11 illustrates a further different exemplary arrangement of the coils 110.

FIG. 12 illustrates a further different exemplary arrangement of the coils 110.

FIG. 13 illustrates a further different exemplary arrangement of the coils 110.

FIG. 14 illustrates a different example of a power source 150.

FIG. 15 illustrates a different configuration of the circuit 100

FIG. 16 illustrates an exemplary circuit which causes multiple cold cathode fluorescent lamps to light up in parallel.

FIG. 17 illustrates an exemplary circuit which steps up a voltage by means of a serial resonance circuit in place of a voltage stepping-up transformer.

FIG. 18 illustrates, as an example, the relation between the frequency and the voltage step-up ratio.

FIG. 19 illustrates an exemplary both-side high-voltage driving circuit.

### DESCRIPTION OF AN EXEMPLARY EMBODIMENT

One aspect of the invention will now be described based on the embodiment, which does not intend to limit the scope of the present invention, but exemplify the invention. All of the features and the combinations thereof described in the embodiment are not necessarily essential to the invention.

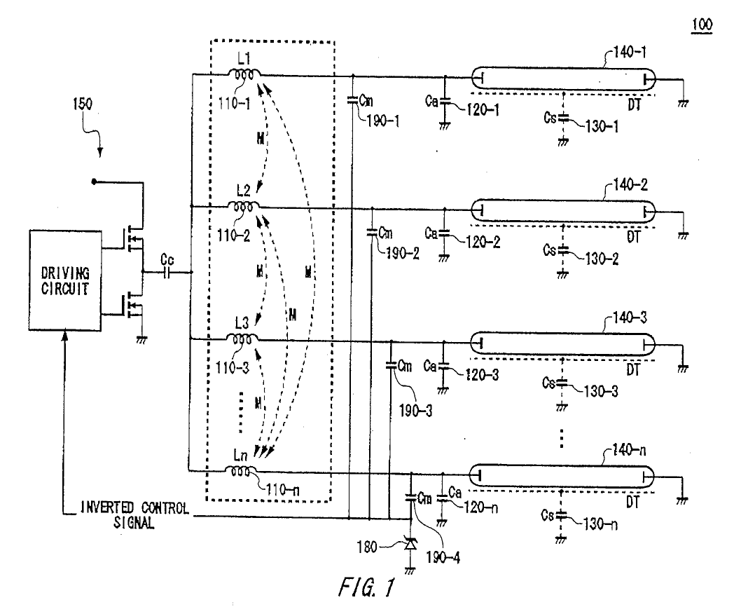

FIG. 1 illustrates an exemplary configuration of a circuit 100 relating to an embodiment. The circuit 100 relating to the present embodiment aims to achieve the following effect Coils 110 included in the circuit 100 are positioned in the vicinity of each other, so that the magnetic fluxes partly oppose each other and thus offset each other. In this way, mutual inductances Mare generated between the coils 110, which results in equalizing the circuit currents of the resonance circuits constituted by using different coils 110. Since no voltage step-up transformers are used, the coils 110 are utilized to step up the voltage. FIG. 1 discloses an actual inverter circuit constituted by the coils 110 which have currents equalized with respect to each other.

The circuit 100 is used to drive a plurality of discharge tubes 140-1 to 140-n (hereinafter collectively referred to as the discharge tubes 140). The circuit 100 includes therein a coil 110-1, a coil 110-2, a coil 110-3, . . . and a coil 110-n (hereinafter collectively referred to as the coils 110), a plurality of resonance capacitors 120-1 to 120-n (hereinafter collectively referred to as the resonance capacitors 120), and a power source 150 to drive the discharge tubes 140. A first circuit includes therein the coil 110-1, resonance capacitor 120-1, and discharge tube 140-1. A second civet includes therein the coil 110-2, resonance capacitor 120-2, and discharge tube 140-2. A third circuit includes therein the coil 110-3, resonance capacitor 120-3, and discharge tube 140-3. An n-th circuit includes therein the coil 110-n, resonance capacitor 120-n, and discharge tube 140-n. Note that the first, second and third coils relating to the present invention may respectively indicate the coils 110-1, 110-2 and 110-3

Each of the coils 110 has substantially the same self inductance. Also, each of the coils 110 has substantially the same mutual inductance M with respect to the respective remaining coils 110. The coils 110 and resonance capacitors 120 form serial resonance circuits. The voltages at both ends of the resonance capacitors 120 are supplied to the discharge tubes 140. Here, the discharge tubes 140-1, 140-2, 140-3, . . . and 140-n respectively have parasitic capacitances 130-1, 130-2, 130-3, . . . and 130-n. In the present embodiment, a capacitance component may denote the total of the capacitance of the resonance capacitor 120 and the parasitic capacitance 130. Alternatively, the coils 110 may each have a parasitic capacitance, and the capacitance component may denote the total of the capacitance of the resonance capacitor 120, the parasitic capacitance 130, and the parasitic capacitance of the coil 110.

As discussed above, the first to n-th circuits respectively have the coils 110 connected to the power source ISO, and the capacitance components. In addition, the first, second, third, . . . and n-th circuits have detection capacitors 190-1, 190-2, 190-3, . . . and 190-n (hereinafter collectively referred to as the detection capacitors 190) to detect the resonance currents of the respective circuits. The detection capacitors 190 are provided in the respective resonance circuits in order to calculate the average of the resonance currents. The currents flowing through the detection capacitors 190 have the same phase as the currents flowing through the resonance capacitors 120. These currents flow into a zener diode 180, and produce rectangular waves having the same phase as the currents. When the voltage of the zener diode 130 is approximately 5 V, the produced voltage waveform is similar to a digital waveform of 0 V to 5 V. By switching on/off the driving circuit in synchronization with the produced voltage waveform, the respective resonance circuits of the first to n-th circuits can be driven at frequencies in the vicinity of the resonance frequencies.

The power source 150 generates AC power by switching on/off, for example, a high-voltage DC power source of the PFC circuit. In the circuit 100, the discharge tubes 140 are directly caused to light up by using, for example, the high-voltage DC power source of the PFC circuit, that is to say, by using no voltage step-up transformers. Since the circuit 100 includes no voltage step-up transformers provided therein, the resonance circuits are required to have very high Q values. Accordingly, the circuit 100 needs to be driven by utilizing a current-resonance-type circuit disclosed by the inventor of the present application in, for example, Unexamined Japanese Patent Application No. 2005-176599. Alternatively, the power source 150 may be connected via a voltage step-up transformer as shown in FIG. 15. If such is the case, the circuit 100 may operate at a frequency within such a range that a difference between the voltage phase and the current phase with respect to the primary winding of the voltage step-up transformer is smaller than a predetermined value. In this way, the power factor with respect to the primary winding of the voltage step-up transformer can be dramatically improved. Here, the improvement of the power factor means that a smaller amount of excitation current flows through the primary winding, which implies that the number of turns of the primary winding can be significantly reduced. Therefore, it becomes possible to reduce the copper loss occurring in the primary winding. As a result, the circuit 100 can be utilized as a high-efficiency inverter circuit for use with discharge tubes.

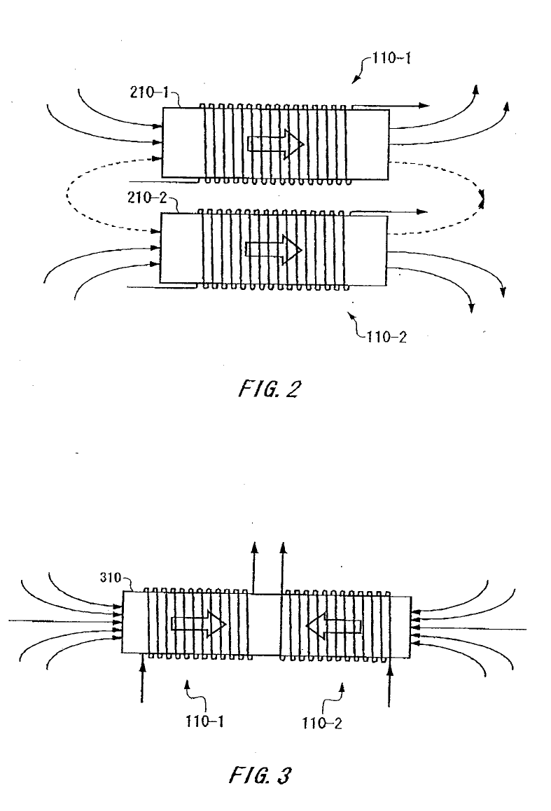

FIG. 2 illustrates an exemplary arrangement of the coils 110-1 and 110-2. The coils 110-1 and 110-2 are respectively formed in such a manner that windings are wound around cores 210-1 and 210-2 (hereinafter collectively referred to as the cores 210). The coil 110-2 is arranged so as to generate a magnetic field in such a direction as to offset the magnetic field generated by the current flowing through the coil 110-1. For example) the coils 110-1 and 110-2 generate magnetic fields in substantially the same direction by means of the power source 150. In addition, the coils 110-1 and 110-2 are positioned in the vicinity of each other. As described above, the coils 110-1 and 110-2 that generate the magnetic fields in substantially the same direction are arranged in parallel to each other so that the magnetic fluxes offset each other.

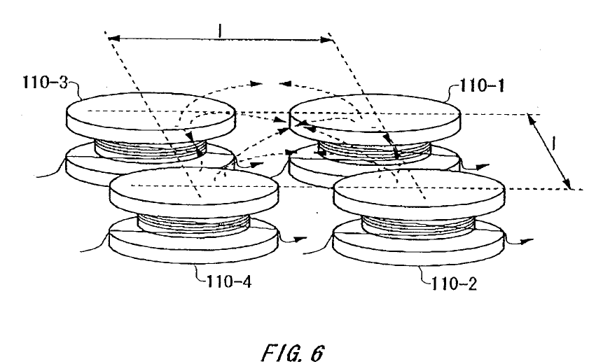

FIG. 3 illustrates a different exemplary arrangement of the coils 110-1 and 110-2. The coils 110-1 and 110-2 are formed by different windings wound around the same core 310. According to this exemplary arrangement, the coils 110-1 and 110-2 oppose each other so that the magnetic fields generated oppose each other. In the present embodiment, the arrangement of the coils 110 is not limited to the examples shown in FIGS. 2 and 3. The coils 110 may be arranged in different manners as long as the magnetic fluxes of the coils 110 offset each other. The different ways of arranging the coils 110 are described with reference to FIGS. 6 to 13.

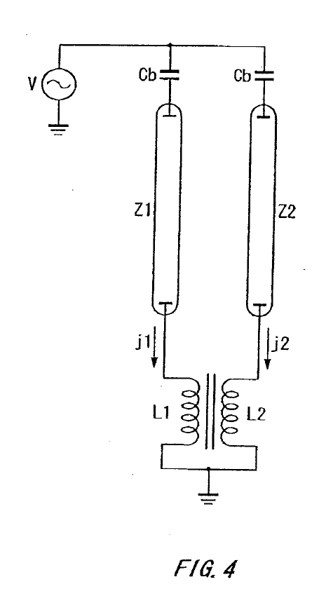

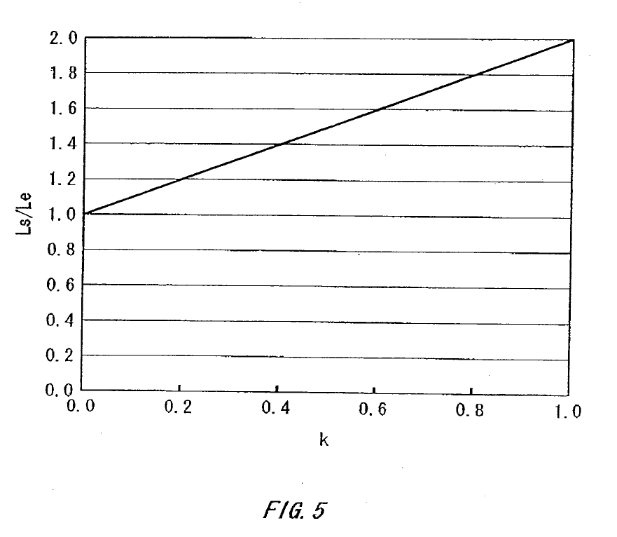

When the coils 110-1 and 110-2 are positioned in the vicinity of each other as illustrated in FIGS. 2 and 3, the magnetic fluxes generated in the coils 110-1 and 110-2 repel each other. As a result, part of the magnetic fluxes disappear. That is to say, the two coils 110 have a mutual inductance M generated therebetween. The mutual inductance M acts to, equalize the currents flowing through the coils 110. The influence of the mutual inductance is described in the following by using an equivalent circuit that is shown in FIG. 4 and disclosed in Unexamined Japanese Patent Application Publication No. 2004-335443 and U.S. Patent Application Publication No. 2004-0155596. Here, the following expression is Cue when V denotes the voltage of the power source, Z1 and Z2 denote the impedances of the discharge tubes, L1 and L2 denote the inductances of the coils, and M denotes the mutual inductance between the coils.

[Expression 1]
V=(Z₁+jωL₁)·j₁−jω·M·j₂ (1)
V=(Z₂+jωL₂)·j₂−jω·M·j₁ (2)

When L1=L2 and the leakage inductance is 0, that is to say, L1=L2=M, the relation been the currents j1 and j2 flowing through the coils can be represented by the following expression.

$$\begin{matrix}[ Expression 2 ] & \\ {j}_{2} = \frac{{Z}_{1} + j ω ( {L}_{1} + M )}{{Z}_{2} + j ω ( {L}_{2} + M )} \cdot {j}_{1} = \frac{{Z}_{1} + 2 j ω \cdot {L}_{1}}{{Z}_{2} + 2 j ω \cdot {L}_{1}} \cdot {j}_{1} & ( 3 )\end{matrix}$$

When 2ωL1 is sufficiently larger than Z1 and Z2, j1 and j2 are substantially the same irrespective of the values of Z1 and Z2. It should be noted here that the leakage inductance components of the coils 110 shunt the current in the present invention. Therefore, the present invention does not particularly require a configuration having a strong current-shunting capability which achieves the effect that “the sum of the mutual inductances exceeds the negative resistances of the discharge tubes” as mentioned in Unexamined Japanese Patent Application Publication No. 2004-335443 and U.S. Patent Application Publication No. 2004-0155596. Such a shunting configuration may or may not be realized in the present invention. The present invention only requires the current equalizing effect.

Here, the shunt coil disclosed in the above-mentioned invention indispensably has a high coupling coefficient. Therefore, the shunt coil needs to be manufactured by using a special method for mass production. For example, the cores are coupled without a gap therebetween (no gaps). On the other hand, the circuit 100 relating to the present embodiment tolerates a leakage inductance of a certain degree (that is to say, he coupling coefficient of the coils 110 is low to a certain degree), and makes use of the leakage inductance for resonance.

In the present embodiment, the cores 210 and 310 are desirably configured in such a manner that one or both of the ends are open. By configuring the cores 210 and 310 in such a manner that one of the ends is open, the effective length of the flux path is increased. Note that the flux path here is proportional to the physical length of the path through which the magnetic flux actually travels, inversely proportional to the cross-sectional area of the magnetic member, and inversely proportional to the magnetic permeability of the magnetic member μiac. The leakage inductance is an unnecessary parameter in the prior invention (Unexamined Japanese Patent Application Publication No. 200.6-012781 and U.S. Patent Application Publication No. 2006-055338). In the present invention, on the other hand, the leakage inductance is an important parameter in constituting the resonance circuit, and must be set as accurately as possible. However, each mass-produced core (for example, a ferrite core) actually has a significantly different magnetic permeability μiac. Therefore, when formed by using cores with their flux paths being closed, coils generally have fairly different inductances from each other.

Considering this issue, one of the ends of each core is made open so that the magnetic flux passes through the air in the present embodiment. In this way, since a portion of the flux path has a large magnetic resistance, the effective magnetic permeability is dominantly determined by the magnetic resistance of the air. As a consequence, even though the cores are different from each other in terms of the magnetic permeability μiac, the inductance variance among the manufactured products can be made very small.

Referring to the example (FIG. 2) where the coils 110 are arranged so as to oppose each other, for example, when both of the ends are made open, the coupling coefficient k between the coils 110 becomes approximately 0.4 to 0.6. In this case, the self inductance of the coils 110 is Lo, and approximately half the self inductance is the mutual inductance M. The mutual inductance M produces the above-described current equalizing effect. The leakage inductance component (1−k)*Lo can contribute to the resonance.

According to the present embodiment, the component which in practice acts as the inductance for the resonance is not exactly equivalent to the above-mentioned leakage inductance (1−k)*Lo. To be specific, there are two types of leakage inductances. One of them is the leakage inductance Le which is recited in the academic documents in the electromagnetic field, and the other is the leakage inductance Ls defined by the JIS measurement method. It is the leakage inductance Ls which numerically contributes directly to the resonance. The leakage inductance Le can be represented by the following expression.
Le=(1−k)*Lo

Also, the following relation is true between Ls and Le.
Ls=(1+k)*Le

Alternatively, the following relational expression also represents the relation between Ls and Le.

$${L}_{s} = \frac{1}{\frac{1}{{L}_{e}} + \frac{1}{M}} \qquad [ Expression 3 ]$$

As indicated by above expression, die value of the leakage inductance is slightly influenced by the mutual inductance M. The relation between Le, Ls and k is shown as a simple linear line as illustrated in FIG. 5. When appearing in the claims directed to the present invention, the leakage inductance means the leakage inductance Ls. The leakage inductance Ls in the claims directed to the present invention is not equivalent to the leakage inductance Le recited in the related academic documents, but is obtained by converting the leakage inductance Le based on the above expression. The leakage inductance Ls directly influences the resonance frequency. Therefore, the resonance frequency fr can be represented by the following expression, when Cw denotes the distributed capacitance of the winding, Ca denotes the capacitance which is appropriately determined to adjust the resonance frequency, and Cs denotes the capacitance component generated around the cold cathode fluorescent lamps, where Cw, Ca and Cs form the resonance capacitance component.

$${f}_{r} = \frac{1}{2 π \cdot \sqrt{{L}_{s} \cdot ( {C}_{w} + {C}_{a} + {C}_{s} )}} \qquad [ Expression 4 ]$$

It should be noted here that the leakage inductances Le and Ls can be converted into each other based on a simple relational expression. Accordingly, the leakage inductances Le and Ls are not distinguishably referred but collectively mentioned as the leakage inductance in the present embodiment for the sake of intelligibility, unless the leakage inductances Le and Ls need to be numerically assessed.

As described above with reference to FIGS. 1 to 5, each of the first to n-th circuits has a serial resonance circuit constituted by the leakage inductance component of one coil 110 and one resonance capacitor 120. Take an example of the first and second circuits respectively including the coils 110-1 and 110-2 shown in FIG. 2. The leakage inductance component of the coil 110-1 and a first capacitance component form a resonance circuit. The leakage inductance component of the coil 110-2 and a second capacitance component form a resonance circuit. Here, He currents flowing through the coils 110-1 and 110-2 are substantially equalized in accordance with the value of the mutual inductance M between the coils 110-1 and 110-2.

Referring to each of the three or more coils 110 included in the circuit 100, the capacitance component of the circuit connected to the coil 110 and the leakage inductance component of the coil 110 constitute a serial resonance circuit. According to an exemplary case where the circuit 100 includes three coils, the leakage inductance component of the coil 110-1 and a first capacitance component form a resonance circuit, the leakage inductance component of the coil 110-2 and a second capacitance component form a resonance circuit, and the leakage inductance component of the coil 110-3 and a third capacitance component form a resonance circuit.

FIG. 6 illustrates a further different exemplary arrangement of the coils 110. FIG. 6 is used to explain an exemplary method to arrange three or more coils 110 in the vicinity of each other. For example, each of the coils 110 is arranged at approximately equal distances from the rest of the coils 110 as illustrated in FIG. 6. When the layout of the printed circuit board is determined in practice, the coils 110 need to be arranged carefully. Unless the coils 110 are arranged evenly, the mutual inductances between the coils 110 which are strongly influenced by the interactions between the coils 110 increase, and the leakage inductances decrease. This increases the resonance frequencies of the resonance circuits formed by using the coils 110, thereby degrading the current equalizing effect.

As illustrated in FIG. 6, the coils 110-1, 110-2, 110-3, and 110-4 are arranged so as to generate, based on the power supplied thereto from the power source 150, magnetic fields in such directions that the generated magnetic fields offset each other. For example, the coils 110-1, 110-2, 110-3, and 110-4 are arranged on substantially the same plane and generate, by using the power source 150, magnetic fields in substantially the same direction, that is to say, in a direction substantially perpendicular to the plane. Furthermore, the distance between the center of the coil 110-1 and the center of the coil 110-2, the distance between the center of the coil 110-1 and the center of the coil 110-3, the distance between the center of the coil 110-2 and the center of the coil 110-4, and the distance between the center of the coil 110-4 and the center of the coil 110-3 are adjusted to be substantially the same (the length l). In this way, the coupling coefficients between the coils 110 are adjusted to be substantially the same. With this configuration, the resonance frequencies can be adjusted substantially the same.

When the circuit 100 includes therein three coils 110, the coils 110-1, 110-2 and 110-3 may be arranged on substantially the same plane so as to generate magnetic fields in a direction substantially perpendicular to the plane and so as to be positioned away from each other with substantially the same distance therebetween. When the coils 110-1, 110-2 and 110-3 are arranged in the above-described manner, the coils 110-1, 110-2 and 110-3 can have substantially the same coupling coefficient with respect to each other.

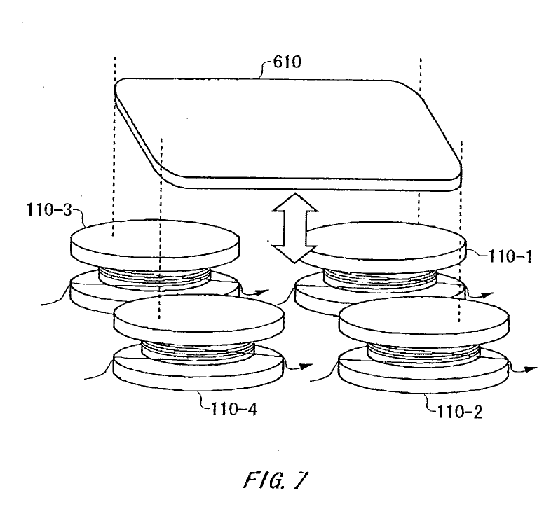

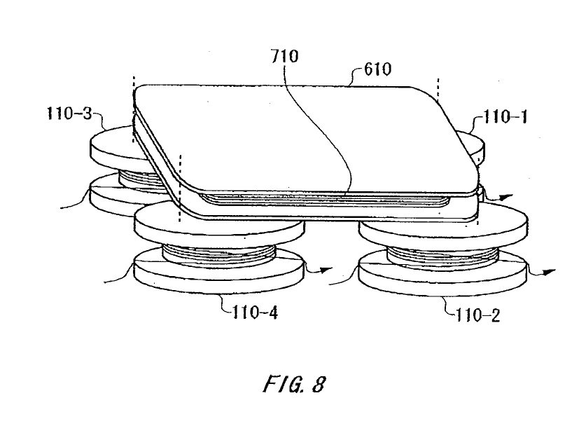

FIG. 7 illustrates a further different exemplary arrangement of the coils 110. According to this exemplary arrangement, a magnetic member 610 is provided in order to further enhance the interactions between the coils 110. The magnetic member 610 is positioned in the vicinity of the coils 110-1, 110-2, 110-3 and 110-4 so as to oppose the magnetic fields generated by the coils 110-1, 110-2, 110-3 and 1104. For example, the magnetic member 610 is provided so as to cover the coils 110-1, 110-2, 110-3 and 110-4. The magnetic member 610 guides the magnetic field generated by the coil 110-1 to the coils 110-2, 110-3 and 110-4, guides the magnetic field generated by the coil 110-2 to the coils 110-1, 110-3 and 110-4, guides the magnetic field generated by the coil 110-3 to the coils 110-1, 110-2 and 110-4, and guides the magnetic field generated by the coils 110-4 to the coils 110-1, 110-2 and 110-3.

When the magnetic member 610 is provided in the vicinity of the coils 110 as illustrated in FIG. 7, the percentage of the self inductances which functional as the mutual inductances, i.e. the coupling coefficients, can be adjusted by adjusting the distance between the magnetic member 610 and the coils 110. The distance between the magnetic member 610 and the coils 110 may be appropriately adjusted so that the coupling coefficients fall with a predetermined range. Alternatively, the distance may be set at zero so that the magnetic member 610 is in contact with the coils 110. When the magnetic member 610 is in contact with the coils 110 with the distance therebetween being set at zero, the resulting configuration is equivalent to the configuration where the respective coils are wound around leg-shaped cores. As described above, by providing the magnetic member 610, the coupling coefficients between the coils 110 can be adjusted to be substantially the same even when the coils 110 can not be positioned away from each other with the same distance therebetween due to restrictions regarding the arrangement of the coils 110.

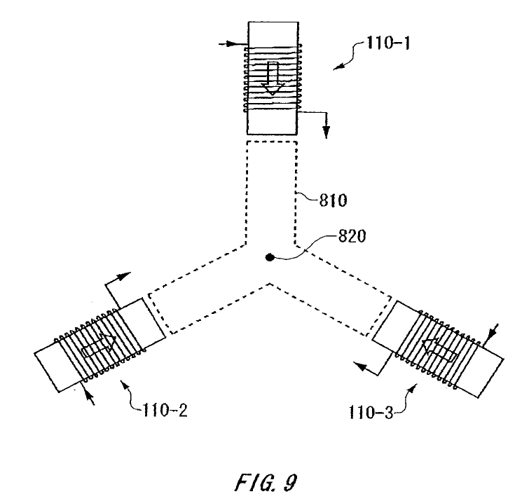

FIG. 8 illustrates a further different exemplary arrangement of the coils 110. When it is required to strengthen the effects produced by the magnetic member 610 which is positioned in the vicinity of the coils 110 in the arrangement shown in FIG. 7, an auxiliary winding 710 is wound around the magnetic member 610 in a direction substantially parallel to the direction in which the windings of the coils 110-1 and 110-2 are wound as shown in FIG. 8, and the terminals of the auxiliary winding 710 are short-circuited. In place of the auxiliary winding 710, a conductive belt may be wound once around the magnetic member 610, and short-circuited. When this arrangement is employed, it is preferable that the coupling coefficient between the auxiliary winding 710 and coil 110-1, the coupling coefficient between the auxiliary winding 710 and coil 110-2, the coupling coefficient between the auxiliary winding 710 and coil 110-3, and the coupling coefficient between the auxiliary winding 710 and coil 1104 are substantially the same.

FIG. 9 illustrates a further different exemplary arrangement of the coils 110. The magnetic axes of the magnetic fields generated by the coils 110-1, 110-2 and 110-3 are directed to substantially the same point 820. The coils 110-1, 110-2 and 110-3 are connected to the power source 150 so as to generate magnetic fields in such directions that the generated magnetic fields offset each other. For example, the coils 110-1, 110-2 and 110-3 generate magnetic fields in directions extending to the point 820 at a given time. The distance between the point 810 and the coil 110-1, the distance between the point 810 and the coil 110-2, and the distance between the point 810 and the coil 110-3 are substantially the same. Also, the angle formed between the magnetic axes of the coils 110-1 and 110-2, the angle formed between the magnetic axes of the coils 110-2 and 110-3, and the angle formed between the magnetic axes of the coils 110-3 and 110-1 are substantially the same. With the above-mentioned configurations, the coils 110-1, 110-2 and 110-3 have substantially the see coupling coefficient with respect to each other. As a result, the tube currents flowing through the discharge tubes 140 connected to the coils 110 are substantially equalized.

Here, a magnetic member 810 may be provided which guides the magnetic field generated by each of the coils 110 to the remaining coils 110. The magnetic member 810 preferably has such a shape that the length of the flux path between the coils 110-1 and 110-2, the length of the flux path between the coils 110-2 and 110-3, and the length of the flux path between the coils 110-3 and 110-1 are made substantially the same. The magnetic member 810 makes it easy to arrange four or more coils 110 in such a manner as to have substantially the same coupling coefficient with respect to each other.

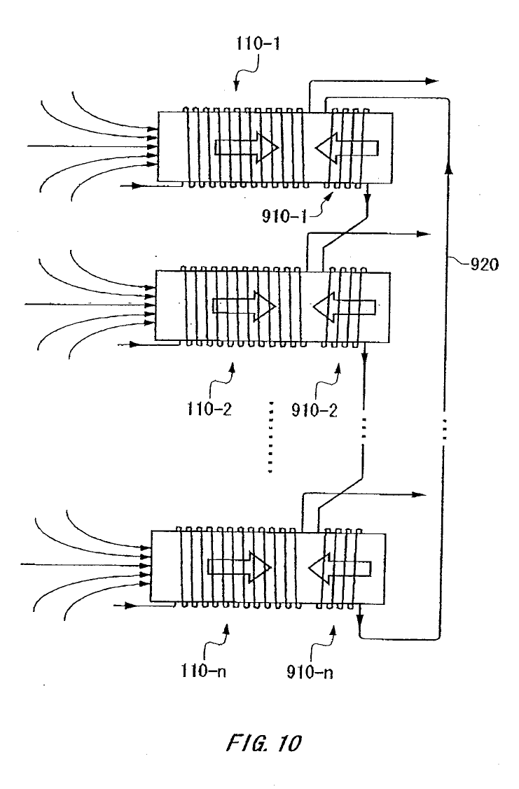

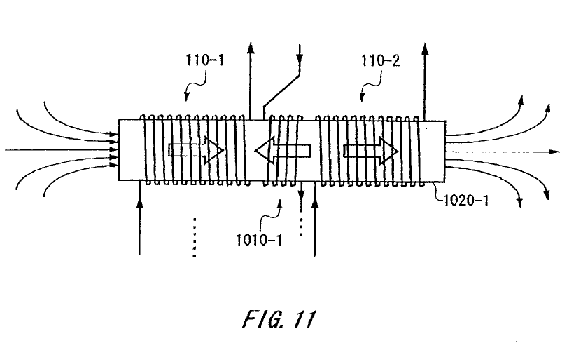

FIG. 10 illustrates a Per different exemplary arrangement of the coils 110. As illustrated in FIG. 10, winding portions 910-1, 910-2, . . . and 910-n (hereinafter collectively referred to as the winding portions 910) are respectively provided on the cores of the coils 110-1, 110-2, . . . and 110-n. The winding portions 910-1, 910-2, . . . and 910-n are magnetically connected mainly to the coils 110-1, 110-2, . . . and 110-n respectively. The coupling coefficient between each of the coils 110 and a corresponding one of the winding portions 910 is substantially the same. For example, the coupling coefficient between the coil 110-1 and the winding portion 910-1 is substantially the same as the coupling coefficient between the coil 110-2 and the winding portion 910-2. By connecting in series the winding portions 910-1, 910-2, . . . and 910-n, a closed circuit 920 is formed.

The closed circuit 920 is formed by connecting in series the winding portions 910, so that the magnetic field generated in the coil 110-1 with the current flowing through the coil 110-1 generates an induced current, in the closed circuit 920, which flows in such a direction as to generate, in the winding portions 910-2 to 910-n, the magnetic fields extending in such a direction as to offset the magnetic fields generated in the remaining coils 110-2 to 110-n with the currents flowing through the coils 110-2 to 110-n. In other words, the winding portions 910 are connected in series to each other so that electromotive forces are generated in the winding portions 910, which Me magnetically connected to the coils 110, in the same direction by the magnetic fields generated in the coils 110.

According to the arrangement illustrated in FIG. 10, by connecting the winding portions 910 to each other, the tube currents flowing through the discharge tubes 140 can be equalized even when the restrictions imposed on the arrangement of circuits make it impossible to position the coils 110 at approximately equal distances. When the coils 110 are arranged in the manner illustrated in FIG. 10, the coupling coefficients are not significantly influenced by the distances between the coils 110, but are dominantly influenced by the effects of the winding portions 910. Here, the winding portions 910 and the coils 110 may be loosely coupled to each other. The coupling coefficients between the coils 110 can be adjusted by the distances between the coils 110 and the winding portions 910. For example, the coupling coefficients between the coils 110 can be decreased by increasing the distances between the coils 110 and the winding portions 910.

FIG. 11 illustrates a further different exemplary arrangement of the coils 110. The coils 110-1 and 110-2 and a winding portion 1010-1 are provided on a single core 1020-1 in such a manner that the magnetic field generated by the winding portion 1010-1 offsets the magnetic field generated by the coil 110-1 and the magnetic field generated by the coil 110-2. For example, the coil 110-1 is arranged on one of the ends of the winding portion 1010-1, and the coil 110-2 is arranged on the other end of the winding portion 1010-1.

As mentioned above, the coil 110-2 in which an opposing magnetic flux is generated is provided on the other side of the winding portion 1010-1 according to the arrangement shown in FIG. 11. The coils 110-1 and 110-2 are provided on the respective ends of the straight core 1020-1 according to the arrangement shown in FIG. 11. This configuration can prevent the coils 110-1 and 110-2 from being directly connected to each other, thereby preventing the disturbance in the current equalization.

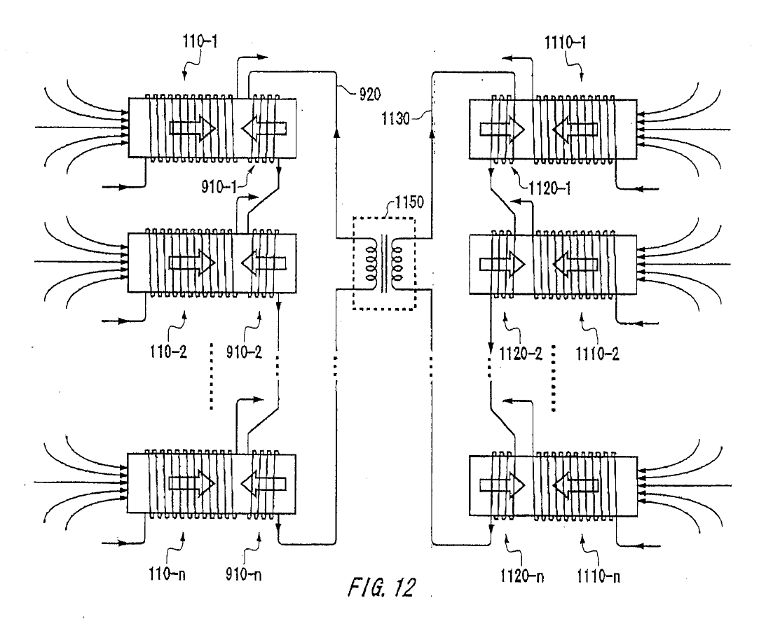

FIG. 12 illustrates a further different exemplary arrangement of the coils 110. The arrangement shown in FIG. 12 is a modification example of the configuration described with reference to FIG. 10. To be specific, the closed circuit of a first structure having the configuration described with reference to FIG. 10 is connected to the closed circuit of a second structure having substantially the same configuration as the first structure, so that the currents flowing through the coils are substantially equalized. According to the arrangement shown in FIG. 12, the first structure including therein the winding portions 910 and coils 110 described with reference to FIG. 10 is connected to the second structure having substantially the same configuration as the first structure by means of a current transformer 1150.

Specifically speaking, coils 1110-1, 1110-2, . . . and 1110-n (hereinafter collectively referred to as the coils 1110) in the second structure have substantially the same characteristics as the coils 110-1, 110-2, . . . and 110-n in the first structure respectively. In addition, winding portions 1120-1, 1120-2, . . . and 1120-n in the second structure have substantially the same characteristics as the winding portions 910-1, 910-2, . . . and 910-n in the first structure. Furthermore, a closed circuit 1130 of the second structure has substantially the same characteristics as the closed circuit 920 of the first structure. The coils 1110-1, 1110-2, . . . and 1110n have resonance capacitors and discharge tubes that have substantially the same characteristics as the resonance capacitors 120 and discharge tubes 140 connected to the coils 110-1, 110-2, 110-3, . . . and 110-n. The coils 1110-1, 1110-2, . . . and 1110-n are connected to such resonance capacitors and discharge tubes in the second structure in a similar manner to the first structure.

The closed circuits 920 and 1130 of the first and second structures are connected to each other via the current transformer 1150. In detail, the closed circuit 920 is positioned on the primary side of the current transformer 1150, and the closed circuit 1130 is positioned on the secondary side of the current transformer 1150. It should be noted that the closed circuits 920 and 1130 are connected to the current transformer 1150 in such a manner that the current generated in the closed circuit 1130 by the current flowing through the closed circuit 920 based on the magnetic fields generated in the coils 110 with the power source 150 is directed in the same direction as the current flowing through the closed circuit 1130 based on the magnetic fields generated in the coils 1110 with the power source 150. According to the arrangement illustrated in FIG. 12, the coils can be coupled to each other with substantially the same coupling coefficient therebetween irrespective of the distances therebetween. The coupling coefficient may be adjusted so as to fall within a predetermined range in order to control the current equalizing effect for the tube currents flowing through the discharge tubes.

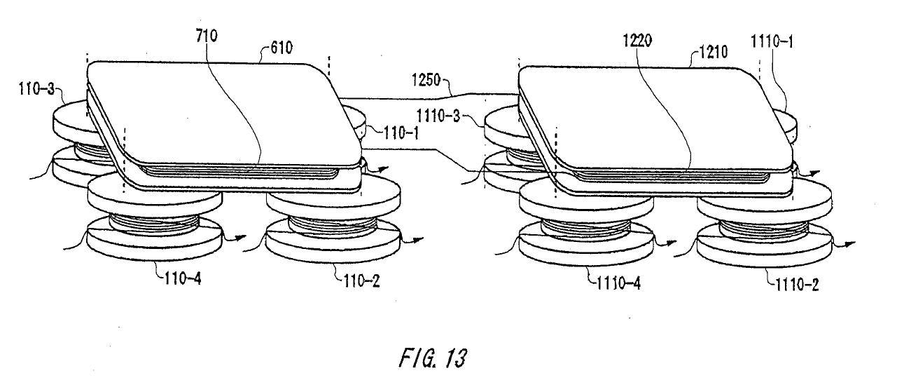

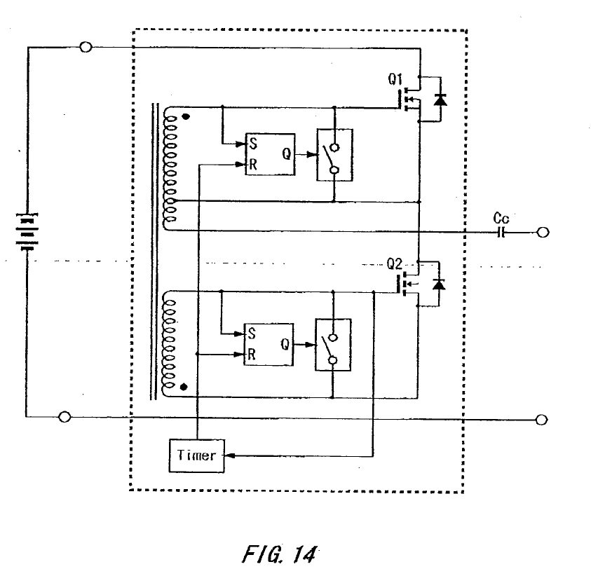

FIG. 13 illustrates a further different exemplary arrangement of the coils 110. The arrangement illustrated in FIG. 13 is a modification example of the configuration illustrated in FIG. 8. To be specific, the auxiliary windings wound around the magnetic members are connected to each other in order to substantially equalize the currents flowing through a first structure having the configuration described with reference to FIG. 8 and a second structure having substantially the same configuration as the first structure. According to the arrangement illustrated in FIG. 13, the first structure including the magnetic member 610 and the coils 110-1 to 110-4 described with reference to FIG. 8 is connected to the second structure having substantially the same configuration as the first structure by means of the auxiliary windings. In this way, the tube currents flowing through the discharge tubes included in the first and second structures are substantially equalized.

Coils 1110-1, 1110-2, 1110-3, and 1110-4 in the second structure respectively have substantially the same characteristics as the coils 110-1, 110-2, 110-3 and 110-4 in the first structure. A magnetic member 1210 has substantially the same characteristics as the magnetic member 610, and an auxiliary winding 1220 having substantially the same characteristics as the auxiliary winding 710 is wound around the magnetic member 1210. The coils 1110-1, 1110-2, 1110-3, and 1110-4 have resonance capacitors and discharge tubes that have substantially the same characteristics as the resonance capacitors 120 and discharge tubes 140 connected to the coils 110-1, 110-2, 110-3 and 110-4. The auxiliary windings 710 and 1220 of the first and second structures form a closed circuit 1250. The auxiliary windings 710 and 1220 of the first and second structures are connected to each other in such a manner that the electromotive force generated in the auxiliary winding 710 by the magnetic fields generated in the coils 110 is directed in the same direction as the electromotive force generated in the auxiliary winding 1220 by the magnetic fields generated in the coils 1110. According to the arrangement illustrated in FIG. 13, the coils can be coupled to each other with substantially the same coupling coefficient therebetween irrespective of the distances therebetween. The coupling coefficient may be adjusted so as to fall within a predetermined range in order to control the current equalizing effect for the tube currents flowing through the discharge tubes.

Needless to say, it is possible to insert a resistance in some of the winding portions or auxiliary windings described with reference to FIGS. 8, 10, 12 and 13 and to detect the current by measuring the voltages at the respective ends of the resistance. Although not illustrated in the drawings describing the present embodiment, the magnetic fluxes may be influenced by a variety of external factors on the circuits in practice. To minimize such influences, the magnetic fluxes may be blocked, or auxiliary magnetic members may be provided. Such modification does not change the principle of the present invention, and can be appropriately made in the present embodiment. It is apparent that the present invention produces a different effect than the provision of such magnetic members.

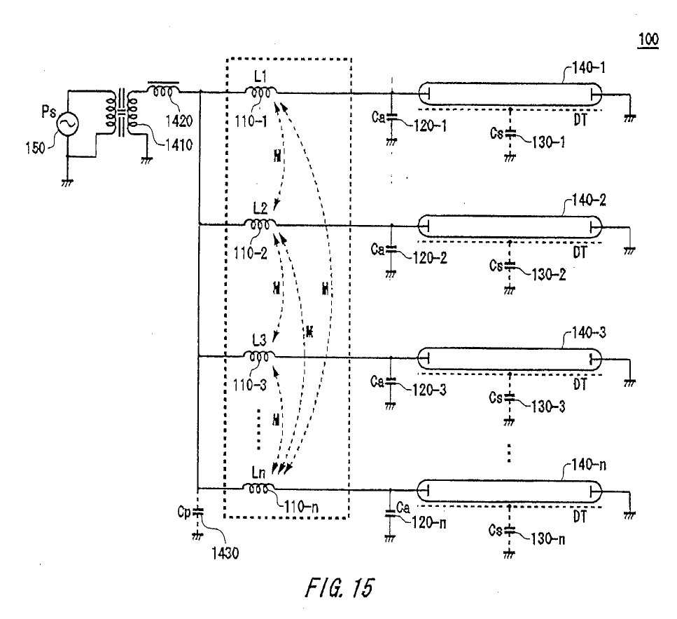

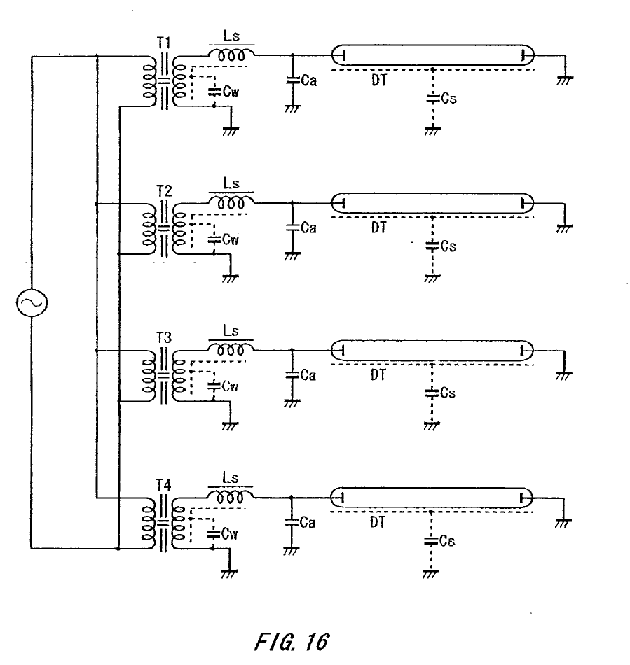

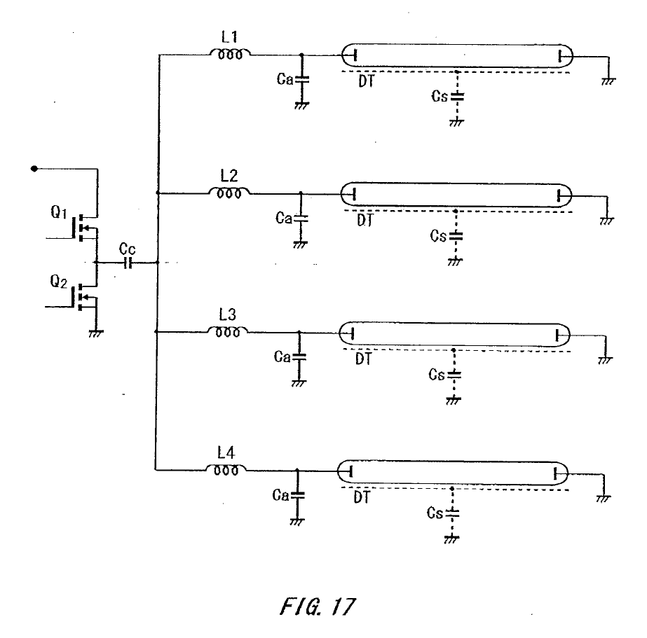

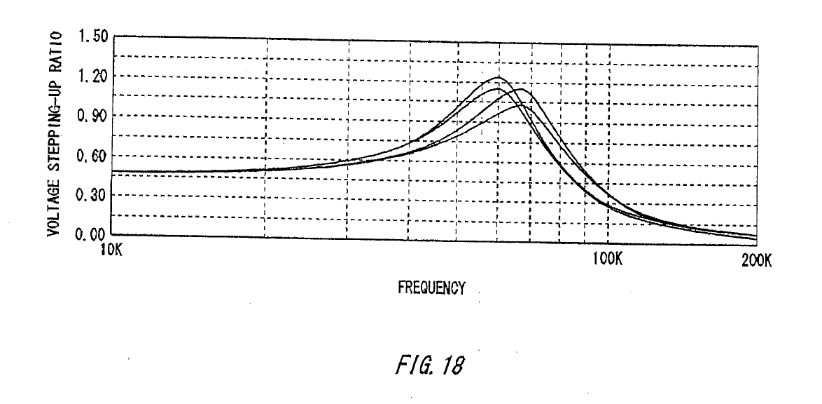

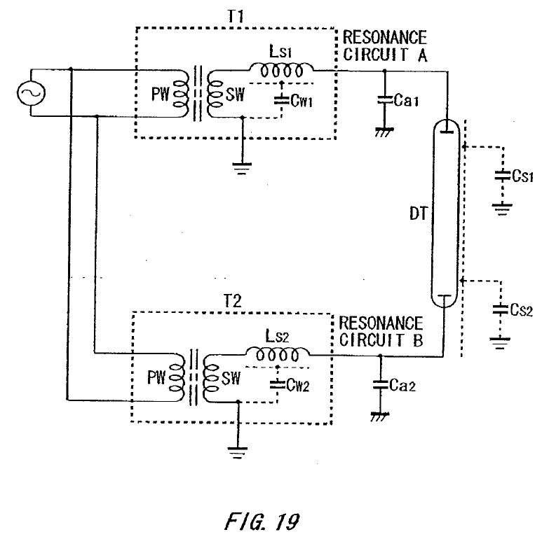

FIG. 14 illustrates another example of the power source 150. The circuit 100 can be driven by using a current-resonance-type circuit. For example, an old-fashioned current-resonance-type circuit or zero-current-switching-type power control means (for example, see Unexamined Japanese Patent Application Publication No H08-288080 by the inventor of the present invention) can be effectively used.

FIG. 15 illustrates a different configuration of the circuit 100. The circuit 100 illustrated in FIG. 15 is substantially the same as the circuit 100 described with reference to FIG. 1, except for a voltage step-up transformer 1410 for stepping up the voltage of the power source 150 and a capacitor 1430 for au adjustment use. Therefore, the following description focuses on the differences. The constituents of the circuit 100 illustrated in FIG. 15 which are assigned the same reference numerals as in FIG. 1 have substantially the same characteristics as the corresponding constituents of the circuit 100 illustrated in FIG. 1. The voltage step-up transformer 1410 steps up the voltage of the power source 150, and supplies the stepped-up voltage to the coils 110. When the voltage step-up transformer 1410 is used as illustrated in FIG. 15, a leakage inductance 1420 of a certain degree is present in the secondary winding of the voltage step-up transformer 1410. This leakage inductance 1420 can be used as the resonance element of the resonance circuits. In this case, however, the inductance values of the resonance circuits may be increased excessively since the resonance is mainly achieved by the coils 110 according to the present invention. If such is the case, the capacitor 1430 for an adjustment use can contribute to find optimal conditions for the resonance.

As described above, the circuit 100 relating to the present embodiment can accomplish substantially equal voltage stepping-up ratios for the voltage stepping-up circuits including resonance circuits. This effect can be produced whether the Q values of the resonance circuits of the secondary-side circuits are increased or decreased. It is particularly important that the variance in current among the discharge tubes is eliminated even when the Q values of the resonance circuits are increased. This advantage indicates that the Q values of the resonance circuits can be increased. Therefore, multiple cold cathode fluorescent lamps can be caused to evenly light up by switching on/off the DC power source of approximately 400 V which is obtained by means of the PFC circuit. As a result, the circuit 100 can cause multiple cold cathode fluorescent lamps to evenly light up without the use of voltage step-up transformers, thereby significantly improving the power efficiency of the circuit used to drive discharge tubes.

Needless to say, it is necessary to utilize a circuit which accurately detect the resonance frequency (e.g. a current-resonance-type circuit) in order to drive the resonance circuits having high Q values (such as the circuit 100) accurately at the predetermined resonance frequency. When used in combination with such a circuit, the circuit 100 can achieve a high voltage stepping-up ratio. In addition the circuit 100 can provide means for reducing the bias phenomenon which may occur when the both-side high-voltage driving method is used.

The above-described embodiment is related to a circuit for equalizing currents with the use of coils. However, it is evident that a variety of modification examples can be produced in combination with the current equalizing methods and driving circuits which have already been disclosed by the inventor of the present invention. Such modification examples are wide-ranging, and thus not explained.

Although one aspect of the present invention has been described by way of an exemplary embodiment, it should be understood that those skilled in the art might make many changes and substitutions without departing from the spirit and the scope of the present invention which is defined only by the appended claims.

As clearly described in the above section, one embodiment of the present invention can provide a circuit that is capable of producing a high voltage at a high efficiency while equalizing currents supplied to a plurality of circuits.

What is claimed is:

1. A circuit comprising:
a first circuit that includes therein a first coil and a first capacitance component; and
a second circuit that includes therein a second coil and a second capacitance component, the second coil being arranged so as to generate a magnetic field in such a direction as to offset a magnetic field generated by a current flowing through the first coil, wherein
a self inductance of the first coil is substantially the same as a self inductance of the second coil,
currents flowing through the first and second coils are made substantially the same by a mutual inductance between the first and second coils,
a leakage inductance component of the first coil and the first capacitance component form a resonance circuit, and
a leakage inductance component of the second coil and the second capacitance component form a resonance circuit.

2. The circuit as set forth in claim 1, further comprising
a third circuit that includes therein a third coil and a third capacitance component, the third coil being arranged so as to generate a magnetic field in such a direction as to offset the magnetic field generated by the current flowing through the first coil and the magnetic field generated by the current flowing through the second coil, wherein
a coupling coefficient between the third and first coils and a coupling coefficient between the third and second coils are substantially the same as a coupling coefficient between the first and second coils, and the currents flowing through the first, second and third coils are adjusted so as to be substantially the same,
a leakage inductance component of the first coil and the first capacitance component form a resonance circuit,
a leakage inductance component of the second coil and the second capacitance component form a resonance circuit, and
a leakage inductance component of the third coil and the third capacitance component form a resonance circuit.

3. The circuit as set forth in claim 1, further comprising
a first closed circuit that includes therein a first winding portion magnetically coupled to the first coil and a second winding portion magnetically coupled to the second coil, the second winding portion and the second coil having a coupling coefficient therebetween which is substantially the same as a coupling coefficient between the first coil and the first winding portion, wherein
the first closed circuit is formed by connecting the first and second winding portions to each other so that the magnetic field generated in the first coil by the current flowing through the first coil generates an induced current in the first closed circuit which flows in such a direction that a magnetic field is generated in the second winding portion in such a direction as to offset the magnetic field generated in the second coil by the current flowing through the second coil.

4. The circuit as set forth in claim 3, comprising:
a first structure that includes therein the first and second circuits and the first closed circuit;
a second structure that includes therein
a fourth circuit that includes therein a fourth coil and a fourth capacitance component,
a fifth circuit that includes therein a fifth coil and a fifth capacitance component, the fifth coil being arranged so as to generate a magnetic field in such a direction as to offset a magnet field generated by a current flowing through the fourth coil, and
a second closed circuit that includes therein a fourth winding portion magnetically coupled to the fourth coil and a fifth winding portion magnetically coupled to the fifth coil, the fifth winding portion and the fifth coil having a coupling coefficient the therebetween which is substantially the same as a coupling coefficient between the fourth coil and the fourth winding portion, wherein
a self inductance of the fourth coil is substantially the same as a self inductance of the fifth coil,
currents flowing through the fourth and fifth coils are made substantially the same,
a leakage inductance component of the fourth coil and the fourth capacitance component form a resonance circuit,
a leakage inductance component of the fifth coil and the fifth capacitance component form a resonance circuit, and
the second closed circuit is formed by connecting the fourth and fifth winding portions to each other so that the magnetic field generated in the fourth coil by the current flowing through the fourth coil generates au induced current in the second closed circuit which flows in such a direction that a magnetic field is generated in the fifth winding portion in such a direction as to offset the magnetic field generated in the fifth coil by the current flowing through the fifth coil; and
a current transformer that has the first closed circuit on a primary side thereof and the second closed circuit on a secondary side thereof.

5. The circuit as set forth in claim 1 further comprising
a magnetic member that is provided in a vicinity of the first and second coils so as to oppose the magnetic fields generated by the first and second coils, the magnetic member guiding the magnetic field generated by the first coil to the second coil and guiding the magnetic field generated by the second coil to the first coil.

6. The circuit as set forth in claim 5, wherein
the first and second coils generate the magnetic fields in substantially the same direction, and
the magnetic member includes
an auxiliary winding that is wound around the magnetic member in a direction substantially parallel to a direction in which a winding of the first coil and a winding of the second coil are wound.

7. The circuit as set forth in claim 6, comprising:
a first structure that includes therein the first and second coils, the magnetic member and the auxiliary winding; and
a second structure that includes therein
a fourth circuit that includes therein a fourth coil and a fourth capacitance component,
a fifth circuit that includes therein a fifth coil and a fifth capacitance component, the fifth coil being arranged so as to generate a magnetic field in such a direction as to offset a magnetic field generated by a current flowing through the folded coil,
a magnetic member that is provided in a vicinity of the fourth and fifth coils so as to oppose the magnetic fields generated by the fourth and fifth coils, the magnetic member guiding the magnetic field generated by the fourth coil to the fifth coil and guiding the magnetic field generated by the fifth coil to the fourth coil, and
an auxiliary winding that is wound around the magnetic member in a direction substantially parallel to a direction in which a winding of the fourth coil and a winding of the fifth coil are wound, wherein
a self inductance of the fourth coil is substantially the same as a self inductance of the fifth coil,
currents flowing through the first and second coils are made substantially the same,
a leakage inductance component of the fourth coil and the fourth capacitance component form a resonance circuit, and
a leakage inductance component of the fifth coil and the fifth capacitance component form a resonance circuit, wherein
the auxiliary winding of the first structure and the auxiliary winding of the second structure form a closed circuit.

8. The circuit as set forth in claim 5, further comprising a third circuit that includes therein a third coil and a third capacitance component, the third coil generating a magnetic field in substantially the same direction as the magnetic fields generated by the first and second coils, wherein
the magnetic member (i) is provided in a vicinity of the first, second, and third coils so as to oppose the magnetic fields generated by the first, second and third coils, (ii) guides the magnetic field generated by the first coil to the second and third coils, (iii) guides the magnetic field generated by the second coil to the first and third coils, (iv) guides the magnetic field generated by the third coil to the first and second coils, and (v) a flux path between the first and second coils, a flux path between the second and third coils, and a flux path between the third and first coils have substantially the same length,
a leakage inductance component of the first coil and the first capacitance component form a resonance circuit,
a leakage inductance component of the second coil and the second capacitance component form a resonance circuit, and
a leakage inductance component of the third coil and the third capacitance component form a resonance circuit.

9. A manufacturing method for manufacturing a circuit, comprising:
forming a first circuit that includes therein a first coil and a first capacitance component;
forming a second circuit that includes therein a second coil and a second capacitance component, the second coil being arranged so as to generate a magnetic field in such a direction as to offset a magnetic field generated by a current flowing through the first coil, the second coil having substantially the same self inductance as the first coil; and
arranging the first and second coils in such a manner that (i) a leakage inductance component of the first coil and the first capacitance component form a resonance circuit, (ii) a leakage inductance component of the second coil and the second capacitance component form a resonance circuit, and (iii) a coupling coefficient between the first and second coils falls within a predetermined range in order that currents flowing through the first and second coils become substantially the same.

10. The manufacturing method as set forth in claim 9, wherein
the arranging includes:
providing a magnetic member in a vicinity of the first and second coils so as to oppose the magnetic fields generated by the first and second coils, the magnetic member guiding the magnetic field generated by the first coil to the second coil and guiding the magnetic field generated by the second coil to the first coil; and
adjusting a distance between the magnetic member and the first and second coils in order that the coupling coefficient between the first and second coils falls within the predetermined range.

11. The manufacturing method as set forth in claim 10, further comprising
forming a third circuit that includes therein a third coil and a third capacitance component, the third coil generating a magnetic field in substantially the same direction as the magnetic fields generated by the first and second coils, the third coil having substantially the same self inductance as the first and second coils, wherein
in the arranging, the first, second and third coils are arranged in such a manner that (i) a leakage inductance component of the first coil and the first capacitance component form a resonance circuit, (ii) a leakage inductance component of the second coil and the second capacitance component form a resonance circuit (iii) a leakage inductance component of the third coil and the third capacitance component form a resonance circuit, and (iv) a coupling coefficient between the first and second coils, a coupling coefficient between the second and third coils, and a coupling coefficient between the third and first coils fall within a predetermined range in order that the currents flowing through the first, second and third coils become substantially the same,
in the magnetic member providing, a magnetic member is provided in a vicinity of the first and second coils so as to oppose the magnetic fields generated by the first, second and third coils, and the magnetic member (I) guides the magnetic field generated by the first coil to the second and third coils, (II) guides the magnetic field generated by the second coil to the first and third coils, and (III) guides the magnetic field generated by the third coil to the first and second coils, and (IV) adjusts a flux path between the first and second coils, a flux path between the second and third coils, and a flux path between the third and first coils so as to have substantially the same length, and
in the distance adjusting, a distance between the magnetic member and the first, second and third coils is adjusted so that the coupling coefficient between the first and second coils, the coupling coefficient between the second and third coils, and the coupling coefficient between the third and first coils fall within the predetermined range.

12. An inverter circuit for use with discharge tubes, comprising:
a first coil connected to a first discharge tube; and
a second coil connected to a second discharge tube, the second coil being arranged so as to generate a magnetic field in such a direction as to offset a magnetic field generated by a current flowing through the first coil, wherein
a self inductance of the first coil is substantially the same as a self inductance of the second coil,
a leakage inductance component of the first coil forms a first resonance circuit together with a first capacitance component that at least includes a capacitance component of the first discharge tube, and
a leakage inductance component of the second coil forms a second resonance circuit together with a second capacitance component that at least includes a capacitance component of the second discharge tube.

13. The inverter circuit as set forth in claim 12, further comprising
a current-resonance-type power source that supplies power to the first and second coils.

14. The inverter circuit as set forth in claim 12, further comprising:
a power source that supplies power to the first and second coils; and
a voltage step-up transformer that steps up the voltage supplied by the power source, and supplies the stepped-up voltage to the first and second resonance circuits, wherein
the power source operates at a frequency within such a range that a difference between a voltage phase and a current phase with respect to a primary winding of the voltage step-up transformer is smaller than a predetermined value.

15. A circuit comprising:
a first circuit that includes therein a first coil;
a second circuit that includes therein a second coil; and
a third circuit that includes therein a third coil, wherein
self inductances of the first, second and third coils are substantially the same,
the first, second and third coils are provided on substantially the same plane and generate magnetic fields in a direction substantially perpendicular to the plane,
the first, second and third coils are positioned away form each other at substantially the same distance, and
coupling coefficients between the first, second and third coils are substantially the same and fall within a predetermined range.

16. A circuit comprising:
a first circuit that includes therein a first coil;
a second circuit that includes therein a second coil; and
a third circuit that includes therein a third coil, wherein self inductances of the first, second and third coils are substantially the same,
magnetic fields generated by the first, second and third coils have magnetic axes extending toward substantially the same point,
the first, second and third coils are positioned away from the point at substantially the same distance,
the first, second and third coils are connected to the power source so as to generate magnetic fields in such directions that the generated magnetic fields offset each other,
an angle formed between the magnetic axes of the first and second coils, an angle formed between the magnetic axes of the second and third coils, and an angle formed between the magnetic axes of the third and first coils are substantially the same, and
coupling coefficients between the first, second and third coils are substantially the same and fall within a predetermined range.
